(19) United States
(12) Patent Application Publication
(10) Pub. No.: US 2006/0170492 A1
(43) Pub. Date: Aug. 3, 2006

(54) Dual-band power amplifier

(76) Inventors: Chang Sheng-Fuh, Hsinchu (TW); Chen Wen-Lin, Hsinchu (TW); Deng Wei-Yin, Hsinchu (TW); Chen Hung-Cheng, Hsinchu (TW); Tang Shu-Fen, Hsinchu (TW); Chen Albert, Hsinchu (TW)

Correspondence Address: Michael D. Bednarek;SHAWPITTMAN LLP, 1650 Tysons Boulevard, McLean, VA, 22102, US

(21) Appl. No.: 11/047,594

(22) Filed: Feb. 2, 2005

(51) Int. Cl. H03G 3/20

(52) U.S. Cl. 330/129

(57) ABSTRACT

The present invention discloses a dual-band power amplifier, capable of operating at a first frequency and a different second frequency simultaneously. The dual-band power amplifier comprises a first gain stage; a second power stage; an input matching unit electrically connected between the first gain stage and a signal input port; an inter-stage matching unit electrically connected between the first gain stage and the second power stage and an output matching unit electrically connected between the second power stage and an output signal port. According to the dual-band power amplifier and the design formula of matching circuit of the present invention, the present invention can simplify the circuit structure and is suitable for various dual-band communication systems.

### BACKGROUND OF THE INVENTION

1. Field of the Invention

The present invention generally relates to a dual-band communication system, and more particularly to a dual-band power amplifier and its matching method.

2. Description of the Related Art

The rapid development of the coexist operation of multi-standard wireless and mobile communication has been driving conventional RF and baseband transceivers to have integrated multi-band and multi-functional characteristics, such as the multimode wireless LAN IEEE802.11 a/b/g card, the integrated Blue-Tooth and wireless LAN card, and the integrated GSM/WLAN handset. This requirement has driven the conventional single-band RF circuits, such as low-noise amplifier (LNA), bandpass filter, mixers, voltage controlled oscillators (VCOs) and power amplifier (PA), to a new design era.

Numbers of work have been demonstrated the different approaches on the dual-band transceiver. For mobile handsets, works by S. Wu and B. Razavi, “A 900-MHz/1.8-GHz CMOS receiver for dual-band applications,” IEEE J. Solid-State Circuits, vol. 33, pp. 2178-2185, December 1998, and J. Tham, M. Margrait, B. Pregardier, C. Hull, R. Magoon, and F. Carr, “A2.7V 900-MHz dual-band transceiver IC for digital wireless communications,” IEEE J. Solid-State Circuits, vol. 34, pp. 282-291, March 1999, use the parallel architecture, which switches between two separated circuits to receive one band at a time. Another design by J. Ryynanen, K. Kivekas, J. Jussia, A. Parssinen, and K. Halonen, entitled “A dual-band RF front-end for WCDMA and GSM applications,” IEEE J. Solid-State Circuits, vol. 364, pp. 1198-1204, August 2001, integrates both parallel WCDMA and GSM receivers into a single signal path to achieve a highly-integrated CMOS chip. On the 2.4/5.2 GHz wireless LANs, the concept of concurrent dual-band receiver was proposed by H. Hashemi and Ali Hajimiri, entitled “Concurrent Multiband Low-Noise Amplifiers-Theory, Design, and Applications,” IEEE Trans. Microwave Theory Tech., Vol. 50, No. 1, pp. 288-301, January 2002, which integrates two independent 2.4-GHz and 5.2-GHz receivers into a single dual-band receiver.

On the dual-band power amplifier, U.S. Pat. No. 6,215,359 issued to Peckham et al., entitled “Impedance matching for a dual-band amplifier”, discloses the matching method of the dual-band power amplifier. The dual-band power amplifier comprises two-stage amplifier and a resonant filtering matching circuit between the two amplifiers, which is used to obtain the maximum output power at 900 MHz and 1800 MHz. In this art, it uses a diode-embedded match network so that the match network provides good match at 900 MHz when the system operates in the GSM mode and it provides another good match at 1800 MHz when the system operates in the DCS mode. Basically it belongs to a switch type amplifier. When the system is operating in one mode, the other mode is disabled. In contrast, for the concurrent dual-mode operation, which means both modes are in active simultaneously, the concurrent dual-band power amplifier is required. In the present invention, a novel concurrent dual-band power amplifier is proposed.

### SUMMARY OF THE INVENTION

It is an objective of the present invention to provide a dual-band power amplifier with concurrent dual-band match network.

It is another objective of the present invention to provide a dual-band power amplifier which can be implemented by the hybrid or monolithic microwave integrated circuits.

To achieve the above objectives, the present invention provides a dual-band power amplifier, capable of operating at a first frequency and at a different second frequency. The dual-band power amplifier comprises a first gain stage, a second power stage, an input matching unit electrically connected between the first gain stage and a signal input port, an inter-stage matching unit electrically connected between the first gain stage and the second power stage, and an output matching unit electrically connected between the second power stage and an output signal port. The first gain stage is used for providing the maximum gain of the dual-band power amplifier. The second power stage is used for providing the maximum power of the dual-band power amplifier. The input matching unit is used for gain match of the dual-band power amplifier. The output matching unit is used for power match of the dual-band power amplifier.

According to one aspect of the dual-band power amplifier, the inter-stage matching unit is used for gain match or power match of the dual-band power amplifier.

According to another aspect of the dual-band power amplifier, the input matching unit, inter-stage matching unit and output matching unit belong to a dual-band L-type architecture having a series branch and a shunt branch. The series branch consists of the first capacitor in series with the first inductor and the shunt branch is composed of the second capacitor in parallel with the second inductor. Simultaneously at the first and the second frequencies, the series branch transfers the input impendence of the next stage, connected to the series branch, to a lower impendence, and the shunt branch transfers the resultant impedance to another stage, connected to the shunt branch.

According to another aspect of the dual-band power amplifier, the first gain stage and the second power stage both are Class AB amplifier.

The dual-band power amplifier with the realization method of the matching circuit according to the present invention simplifies the circuit design for dual-band applications. Moreover, the dual-band power amplifier according to the present invention can be implemented with the hybrid or monolithic microwave integrated circuit technologies with lower cost.

### BRIEF DESCRIPTION OF THE DRAWINGS

All the objects, advantages, and novel features of the invention will become more apparent from the following detailed descriptions when taken in conjunction with the accompanying drawings.

FIG. 1 shows a schematic of a dual-band power amplifier according to the first embodiment of the present invention;

FIG. 2 indicates the power amplifier classification according to the quiescent operating point;

FIG. 3 shows a demonstrated circuit diagram of the dual-band power amplifier in FIG. 1 according to the first embodiment of the present invention;

FIG. 4 shows the equivalent circuit of the dual-band matching network of the matching units in FIG. 1 according to the first embodiment of the present invention;

FIG. 5 shows the trajectory on the Smith chart of the dual-band matching network;

FIG. 6 shows the simulated and measured input return loss of the demonstrated dual-band power amplifier;

FIG. 7 shows the measured output P_{1dB} and power-added efficiency of the dual-band power amplifier according to the present invention at 2.4 GHz; and

FIG. 8 shows the measured output P_{1dB} and power-added efficiency of the dual-band power amplifier according to the present invention at 5.25 GHz.

### DETAILED DESCRIPTION OF THE PREFERRED EMBODIMENT

Although the invention has been explained in relation to several preferred embodiments, the accompanying drawings and the following detailed descriptions are the preferred embodiment of the present invention. It is to be understood that the following disclosed descriptions will be examples of present invention, and will not limit the present invention into the drawings and the special embodiment.

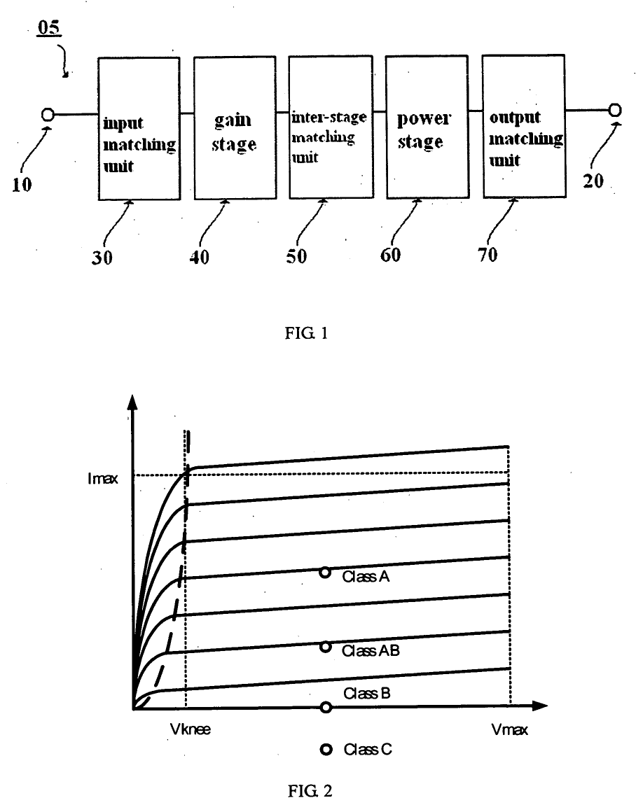

Referring to FIG. 1, it shows a schematic of a dual-band power amplifier according to the first embodiment of the present invention. The dual-band power amplifier 05 comprises a first gain stage 40; a second power stage 60; an input matching unit 30 electrically connected between the first gain stage and a signal input port 10 of the dual-band power amplifier 05; an inter-stage matching unit 50 electrically connected between the first gain stage 40 and the second power stage 60; and an output matching unit 70 electrically connected between the second power stage 60 and an output signal port 20 of the dual-band power amplifier 05. The first gain stage 40 is used for providing the maximum gain of the dual-band power amplifier 05. The second power stage 60 is used for providing the maximum power of the dual-band power amplifier 05. The input matching unit 30 is used for gain match of the dual-band power amplifier 05. The output matching unit 70 is used for power match of the dual-band power amplifier 05.

The first gain stage 40 and the second power stage 60 are designed such that it offers flat gain over the desired passband range. The transistor of gain stage and power stage can be implemented by using Bipolar Junction Transistor (BJT), Heterojunction Bipolar Transistor (HBT), High Electronic Mobility Transistor (HEMT), Pseudomorphic HEMT (PHEMT), Complementary Metal Oxide Semiconductor Filed Effect Transistor (CMOS) and Laterally Diffused Metal Oxide Semiconductor Filed Effect Transistor (LDMOS). Preferably, PHEMT is suitable for the gain stage and power stage in the microwave to millimeter wave range. Semiconductor materials broadly applicable to the gain stage and power stage include: silicon, silicon-on-insulator (SOI), silicon-germanium (SiGe), gallium arsenide (GaAs), indium phosphide (InP) and silicon-germanium-carbon (SiGe—C) materials.

The first gain stage 40 and the second power stage 60 biased at different conditions will have different performances on the output power, linearity, power gain and power-added efficiency. Referring to FIG. 2, it shows the power amplifier classification of quiescent operating point at different DC bias.

(a) Class A amplifier: It is biased at I_{c(max)}/2 in the linear region of the transistor. Since the signal is of full swing with negligible distortion caused by cutoff or saturation, the linearity is of the best among various power amplifier classes. However, the transistor takes half of the whole DC power consumption such that the transistor has lower efficiency, theoretically limited to 50%.

(b) Class B amplifier: The Class-B transistor is biased at the cut-off point and it is activated by the input RF signal swing such that the working period is only half of the input signal. Consequently, Class-B amplifier has higher harmonic distortion and hence lower linearity than the Class-A amplifier. In an ideal condition, the highest efficiency of Class B transistor is 78.5%.

(c) Class AB amplifier: The bias point of Class AB transistor lies between Class A and Class B conditions. The amplifier has improved harmonic distortion than Class B amplifier but has a reduced efficiency.

(d) Class C amplifier: The Class C amplifier is biased in the deep cutoff region such that the RF conduction angle is smaller 180 degrees, which induces rich higher-order harmonics. The Class C amplifier belongs to a highly nonlinear amplifier. It has higher power-added efficiency, trading off with high distortion. As the conduction angle approaches to 0 degree, the power-added efficiency can theoretically reach 100%.

Since the bias condition of the amplifier will determine the performance such as output power, linearity, power gain and power added efficiency, the first gain stage 40 and the second power stage 60 are operated in the Class AB mode in the present invention.

In the present invention, the input matching unit 30 is used for matching the maximum gain of the dual-band power amplifier 05. The output matching unit 70 is used for matching the maximum power of the dual-band power amplifier 05. The inter-stage matching unit 50 electrically connected between the first gain stage 40 and the second power stage 60 can be designed for gain match or power match. When the output power of the first gain stage 40 is sufficient to drive the second power stage 60, the inter-stage matching unit 50 is used for gain match. Otherwise, the inter-stage matching unit 50 is used for power match.

From the general-known knowledge in the RF amplifier area, the gain match can be achieved by making the matching network complex-conjugated to the input impendence of the connected stage. The power match can be achieved by nonlinear simulation of power amplifier circuit, by Cripps rule, or by load pulling technique.

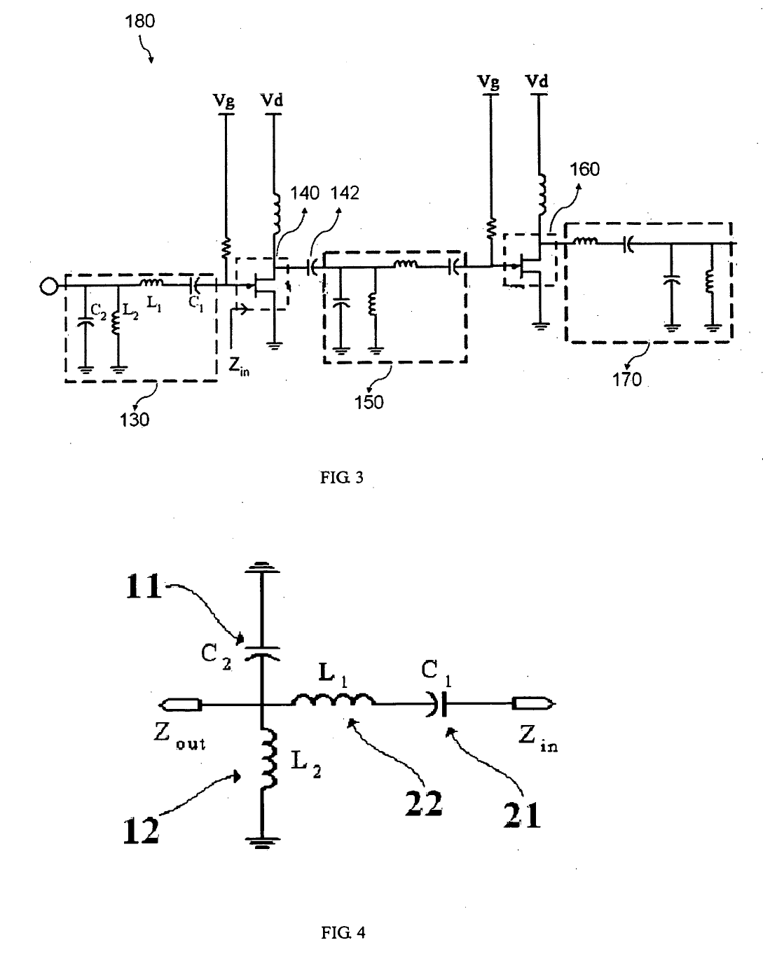

Referring to FIG. 3, it shows the practical circuit of the dual-band power amplifier in FIG. 1 according to the first embodiment of the present invention. The input matching unit 130, inter-stage matching unit 150 and output matching unit 170 belong to a dual-band L-type architecture having a series branch and a shunt branch. The series branch consists of the first capacitor in series with the first inductor and the shunt branch is composed of the second capacitor in parallel with the second inductor. The first gain stage 140 and the second power stage 160 are realized with properly-biased transistors. A capacitor 142 is used to block the DC current and propagates the RF signal of the first gain stage 140 to the inter-stage matching unit 150. The DC bias current, originated from the DC power supply, flows through an inductor of the RF chocking connected between the first gain stage 140 and the voltage source V_{d}.

Since the power amplifier 05 of the present invention simultaneously works for two frequency bands, the input matching unit 30, the inter-stage matching unit 50 and the output matching unit 70 need to simultaneously match at two frequencies. This is a significantly different design methodology from the prior-art single-band match theory. Referring to FIG. 4, it shows the equivalent circuit of the dual-band L-type match network of the matching units in FIG. 1 according to the first embodiment of the present invention. The input matching unit 30, inter-stage matching unit 50 and output matching unit 70 constitute a novel dual-band match architecture having a first capacitor C₁ 21 in series with a first inductor L₁ 22 and a second capacitor C₂ 11 in parallel with a second inductor L₂ 12.

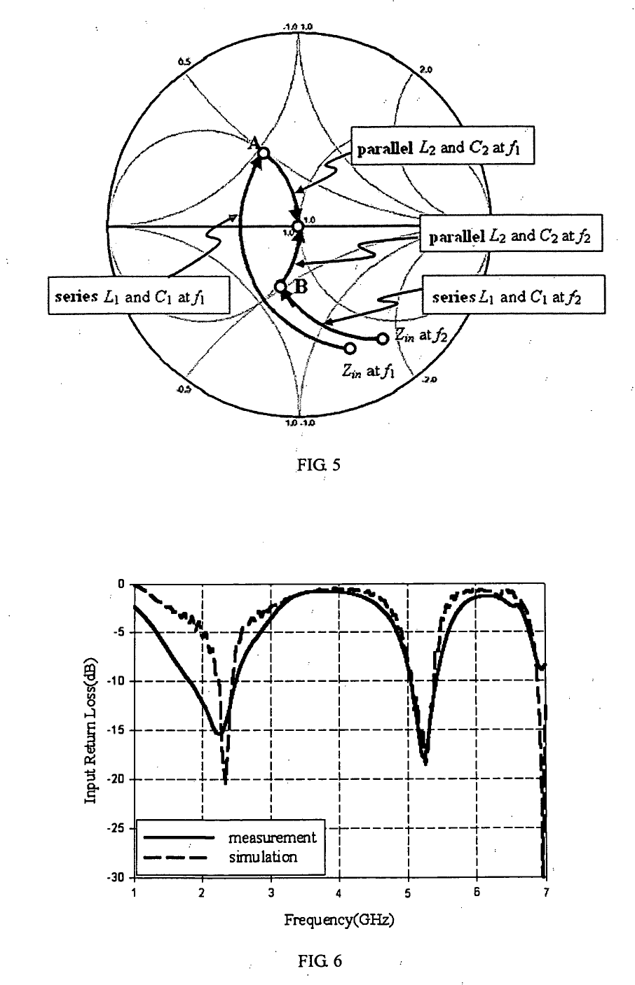

By taken the input stage 130 as an example, FIG. 5 shows the trajectory on the Smith chart of the dual-band L-type match network. The first capacitor C₁ 21 in series with the inductor L₁ 22 are used to transfer the input impendence of the first gain stage 40 to a lower impendence, and the effective impedances of then the second capacitor C₂ 11 in parallel with the second inductor L₂ 12 are used to transfer the resultant impendence to 50Ω at the first and second frequencies simultaneously. The detailed descriptions are followed. Let the impedance of the first gain stage be denoted Zᵢₙ, where Zᵢₙ has different impedance values at different frequencies (f₁ and f₂, f₁>f₂), as shown as one general condition in the figure. The first capacitor C₁ 21 in series with the first inductor L₁ 22 is inductive at f₁ so that Zᵢₙ at f₁ is moved to Point A. If he second capacitor C₂ 11 in parallel with the second inductor L₂ 12 expresses capacitive at f₁, Point A is moved to 50Ω by a proper value set of C₂ and L₂. On the other hand, if the first capacitor C₁ 21 in series with the first inductor L₁ 22 becomes capacitive at f₂, Zᵢₙ at f₂ is shifted to Point B. At this time, if the second capacitor C₂11 in parallel with the second inductor L₂ 12 express inductive at f₂, Point B will be shifted to 50Ω. The exact mathematic derivation is followed in the next section.

Let Zᵢₙ be the input impedance of the first gain stage, where it is R_{A}+jX_{A} and R_{B}+jX_{B} at the first and second frequencies, respectively. Zᵢₙ will become Z_{P} after combined in series with the first capacitor C₁ 21 and the first inductor L₁ 22. Then Z_{P} at the first and second frequencies becomes

$$\{ \begin{matrix}{Z}_{P} ( {ω}_{1} ) = {R}_{A} + j ( {X}_{A} - \frac{1}{{ω}_{1} {C}_{1}} + {ω}_{1} {L}_{1} ) \\ {Z}_{P} ( {ω}_{2} ) = {R}_{B} + j ( {X}_{B} - \frac{1}{{ω}_{2} {C}_{1}} + {ω}_{2} {L}_{1} )\end{matrix} \qquad ( 1 )$$

where ω₁ and ω₂ are the angular frequencies at the first and second frequencies (ω₁>ω₂).
Then by combining in parallel with the second capacitor C₂ 11 and the second inductor L₂ 12, the impedance Z_{P} is transformed into Z_{Q}(=1/Y_{Q})

$$\{ \begin{matrix}{Y}_{Q} ( {ω}_{1} ) = \frac{1}{{Z}_{P} ( {ω}_{1} )} + {jω}_{1} {C}_{2} - j \frac{1}{{ω}_{1} {L}_{2}} \\ {Y}_{Q} ( {ω}_{2} ) = \frac{1}{{Z}_{P} ( {ω}_{2} )} + {jω}_{2} {C}_{2} - j \frac{1}{{ω}_{2} {L}_{2}}\end{matrix} . \qquad ( 2 )$$

At this moment, Z_{Q} must match to the characteristic impedance Z₀, which is 50Ω in general. Therefore, the element values L₁, L₂, C₁, and C₂ can be obtained by solving Eq. (2):

$$\begin{matrix}{L}_{1} = \frac{{ω}_{1} \sqrt{{Z}_{o} {R}_{A} - {R}_{A}^{2}} + {ω}_{2} \sqrt{{Z}_{o} {R}_{B} - {R}_{B}^{2}} - {ω}_{1} {X}_{A} + {ω}_{2} {X}_{B}}{{ω}_{1}^{2} - {ω}_{2}^{2}} & ( 3 ) \\ {C}_{1} = \frac{{ω}_{1}^{2} - {ω}_{2}^{2}}{{ω}_{1} {ω}_{2}} \frac{1}{{ω}_{2} \sqrt{{Z}_{o} {R}_{A} - {R}_{A}^{2}} + {ω}_{1} \sqrt{{Z}_{o} {R}_{B} - {R}_{B}^{2}} - {ω}_{2} {X}_{A} + {ω}_{1} {X}_{B}} & ( 4 ) \\ {L}_{2} = \frac{{ω}_{1}^{2} - {ω}_{2}^{2}}{{ω}_{1}^{2} {ω}_{2}^{2}} {R}_{A} {R}_{B} {Z}_{o} {C}_{1} [ \frac{1}{( {R}_{a} {X}_{B} - {X}_{A} {R}_{B} ) {C}_{1} + ( {R}_{B} - {R}_{A} ) {L}_{1} {C}_{1}} + \frac{{ω}_{1}^{2} {ω}_{2}^{2}}{{ω}_{1}^{2} {R}_{A} - {ω}_{2}^{2} {R}_{B}} ] & ( 5 ) \\ {C}_{2} = \frac{{R}_{A} - {R}_{B} + {ω}_{2} {R}_{A} {C}_{1} {X}_{B} - {ω}_{1} {R}_{B} {C}_{1} {X}_{A} + ( {ω}_{1}^{2} {R}_{B} - {ω}_{2}^{2} {R}_{A} ) {L}_{1} {C}_{1}}{{R}_{A} {R}_{B} {Z}_{o} {C}_{1} ( {ω}_{1}^{2} - {ω}_{2}^{2} )} & ( 6 )\end{matrix}$$

As a numerical example, the dual-band power amplifier 05 is designed at 2.44 GHz and 5.25 GHz. The first gain stage 40 and the second power stage 60 are GaAs PHEMT TC2481 and TC2571, respectively. The first gain stage 40 is biased at V_{ds}=8 V and I_{c}=100 mA, and the second power stage 60 which provides RF power is biased at V_{ds}=8 V and I_{c}=250 mA. Under this bias condition, the input impedance Zᵢₙ of the first gain stage 40 at 2.44 GHz and 5.25 GHz are 8.45-j23.9Ω and 8.15-j11.1Ω. The element values of the input matching unit 30 using the dual matching network in the FIG. 4 are evaluated from Eq. (3)-(6): L₁=1.05 nH, C₁=5.96 pF, L₂=0.78 nH, and C₂=2.55 pF. In a similar way, the device values of the capacitor and the inductor in the inter-stage matching unit 50 and the output matching unit 70 can be obtained. After attaining the initial element values, the whole circuit is optimized by using microwave circuit simulators, such as ADS or other tools, to include the layout and discontinuity parasitics. It is noted that the dual-band power amplifier 05 can be fabricated by the hybrid or monolithic integrated circuit technology.

Referring to FIG. 6, it shows the input return loss of the dual-band power amplifier. The simulated input return loss is greater than 7.5 dB at 2400-2484 MHz and greater than 12.9 dB at 5150-5350 MHz. The measured input return loss is greater than 10.3 dB at 2400-2484 MHz and greater than 13 dB at 5150-5350 MHz. The good agreement between simulation and measurement confirms that the proposed dual-band matching network can achieve good match simultaneously at 2.4 and 5.2 GHz.

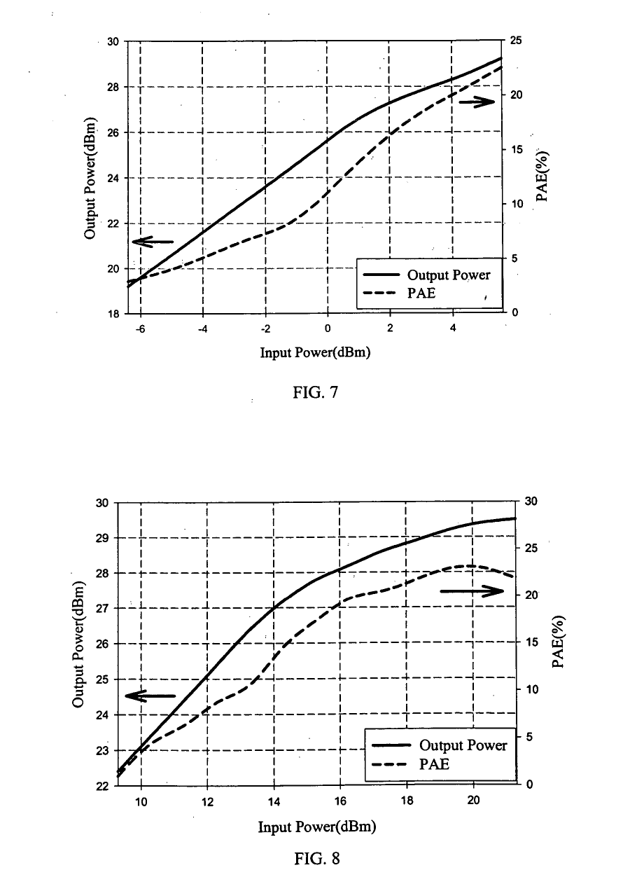

Referring to FIG. 7, it shows the measured output P_{1dB} and power-added efficiency (PAE) of the dual-band power amplifier according to the present invention at 2.44 GHz.

The 1-dB compression point means that the power gain is lower than linear power gain by 1 dB. At 2.44 GHz, the measured output P_{1dB} is 28 dBm and measured PAE at P_{1dB} is 20.3%.

Referring to FIG. 8, it shows the measured output P_{1dB} and power-added efficiency of the dual-band power amplifier according to the present invention at 5.25 GHz. At 5.25 GHz, the measured output P_{1dB} is 27.9 dBm and measured PAE at P_{1dB} is 20%. This shows the output dual-band match network designed by the proposed method can achieve excellent power match simultaneously at 2.4 and 5.2 GHz.

From the above description, the dual-band power amplifier according to the present invention can obtain high gain and power output simultaneously at different frequencies. Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A dual-band power amplifier, capable of operating at a first frequency and a different second frequency simultaneously, comprising:
a first gain stage, used for providing the maximum gain of the dual-band power amplifier;
a second power stage, used for providing the maximum power of the dual-band power amplifier;
an input matching unit electrically connected between the first gain stage and a signal input port, used for gain match of the dual-band power amplifier;
an inter-stage matching unit, electrically connected between the first gain stage and the second power stage, and
an output matching unit, electrically connected between the second power stage and an output signal port, used for power match of the dual-band power amplifier.

2. A dual-band power amplifier as claimed in claim 1, wherein the inter-stage matching unit is used for gain match of the dual-band power amplifier.

3. A dual-band power amplifier as claimed in claim 1, wherein the inter-stage matching unit is used for power match of the dual-band power amplifier.

4. A dual-band power amplifier as claimed in claim 1, wherein the input matching unit, inter-stage matching unit and output matching unit belong to a dual-band match architecture having a series branch and a shunt branch. The series branch consists of the first capacitor in series with the first inductor and the shunt branch is composed of the second capacitor in parallel with the second inductor.

5. A dual-band power amplifier as claimed in claim 4, wherein the series branch transfers the input impendence of the next stage connected to the series branch to a lower impendence, and the shunt branch transfers the resultant impedance to another stage connected to the shunt branch simultaneously at the first and the second frequencies.

6. A dual-band power amplifier as claimed in claim 1, wherein the inter-stage matching unit is used for gain match of the dual-band power amplifier when the output power of the first gain stage is sufficient to drive the second power stage.

7. A dual-band power amplifier as claimed in claim 1, wherein the first gain stage is a Class AB amplifier.

8. A dual-band power amplifier as claimed in claim 1, wherein the second power stage is a Class AB amplifier.

9. A dual-band power amplifier as claimed in claim 1, wherein the first gain stage and the second gain stage are selected from one of the group including bipolar junction transistor (BJT), heterojunction bipolar transistor (HBT), high Electronic mobility transistor (HEMT), pseudomorphic HEMT (PHEMT), complementary metal oxide semiconductor filed effect transistor (CMOS) and laterally diffused metal oxide semiconductor filed effect transistor (LDMOS).

10. A dual-band power amplifier as claimed in claim 1, where in the dual-band power amplifier is fabricated with the hybrid or the monolithic microwave integrated circuit technology.

11. A dual-band power amplifier, capable of operating at a first frequency and a different second frequency, comprising:
a first Class AB amplifier, used for providing the maximum gain of the dual-band power amplifier;
a second Class AB amplifier, used for providing the maximum power of the dual-band power amplifier;
an input matching unit electrically connected between the first gain stage and a signal input port, used for matching the maximum gain of the dual-band power amplifier;
an inter-stage matching unit, electrically connected between the first gain stage and the second power stage, and
an output matching unit, electrically connected between the second power stage and an output signal port, used for matching the maximum power of the dual-band power amplifier.

12. A dual-band power amplifier as claimed in claim 11, wherein the inter-stage matching unit is used for power match of the dual-band power amplifier.

13. A dual-band power amplifier as claimed in claim 11, wherein the input matching unit, inter-stage matching unit and output matching unit belong to a dual-band match architecture having a series branch and a shunt branch. The series branch consists of the first capacitor in series with the first inductor and the shunt branch is composed of the second capacitor in parallel with the second inductor.

14. A dual-band power amplifier as claimed in claim 13, wherein the series branch transfers the input impendence of the next stage connected to the series branch to a lower impendence and the shunt branch transfers the resultant impedance to another stage connected to the shunt branch simultaneously at the first and the second frequencies.

15. A dual-band power amplifier as claimed in claim 11, wherein the inter-stage matching unit is used for power match of the dual-band power amplifier when the output power of the first Class AB amplifier is insufficient to drive the second AB class amplifier.

16. A dual-band power amplifier as claimed in claim 11, wherein the first Class amplifier and the second Class AB amplifier are selected from one of the group including bipolar junction transistor (BJT), heterojunction bipolar transistor (HBT), high Electronic mobility transistor (HEMT), pseudomorphic HEMT (PHEMT), complementary metal oxide semiconductor filed effect transistor (CMOS) and laterally diffused metal oxide semiconductor filed effect transistor (LDMOS).

17. A dual-band power amplifier as claimed in claim 11, where in the dual-band power amplifier is fabricated with the hybrid or the monolithic microwave integrated circuit technology.
